(19) United States
(12) Patent Application Publication
(10) Pub. No.: US 2015/0159263 A1
(43) Pub. Date: Jun. 11, 2015

(54) EVAPORATION DEVICE

(71) Applicant: SHENZHEN CHINA STAR OPTOELECTRONICS TECHNOLOGY CO., LTD., Shenzhen, Guangdong (CN)

(72) Inventors: Qinghua Zou, Shenzhen (CN); Chang Chengmr LO, Shenzhen (CN); Yi-Fan Wang, Shenzhen (CN)

(21) Appl. No.: 14/240,347

(22) PCT Filed: Jan. 22, 2014
(86) PCT No.: PCT/CN2014/071068

§ 371 Date: Feb. 21, 2014

(30) Foreign Application Priority Data
Oct. 12, 2013 (CN) 201310475906.4

(51) Int. Cl. C23C 14/24

(52) U.S. Cl. CPC C23C 14/243

(57) ABSTRACT

The present disclosure relates to an evaporation device, including an evaporation device body, within which a plurality of thermal conductors that are contacted with one another for thermal conduction is disposed, wherein several holes are provided in each of the thermal conductors, and coating material for evaporation are provided within the holes of the thermal conductors, the spaces formed between the thermal conductors and the evaporation device body, and/or the spaces formed among the thermal conductors. With this evaporation device, better heat transfer can be achieved so that the overall heating temperature can be reduced, thus minimizing decomposition of organic material.

### TECHNICAL FIELD

The present disclosure relates to a heating device, and specifically to an evaporation device which can be used as an evaporation source for heating and vaporizing material to be coated and depositing it onto the surface of a substrate or a workpiece.

### TECHNICAL BACKGROUND

An organic light-emitting device is a kind of self-luminous device, having such advantages as low working voltage, wide viewing angle, fast response speed, good thermal adaptability and no on. With regard to the molecular weights of the organic light-emitting materials as used, the organic light-emitting devices can be divided into small molecule organic light-emitting devices (OLEDs) and polymer light-emitting devices (PLEDs). On account of different molecular weights of the materials as used, the processes of manufacturing the organic light-emitting devices are also very different. For example, PLEDs are generally produced by spin coating or ink-jet printing, while OLEDs are mainly produced by thermal evaporation.

In thermal evaporation, organic materials are heated under vacuum environment (E-5 Pa) by an OLED evaporation device to the extent that the organic materials, which can be sublimated or melted, are vaporized under a high temperature, and thereafter deposited onto a substrate with a TFT structure or an anode structure. Currently, there are two prevailing evaporation sources, i.e., point evaporation source and linear evaporation source. The point evaporation source is small in size, and therefore, many of them can be installed in one coating chamber and various kinds of material can be filled therein. This point evaporation source is mainly used in labs and in earlier mass production lines. In the linear evaporation source, the utilization rate of material and the uniformity of film thickness are both superior to those of the point evaporation source. Therefore, most of the mass production lines recently constructed employ the linear evaporation source.

Generally speaking, the difference between evaporation temperature and decomposition temperature of organic material is quite tiny. However, the temperature difference inside a crucible generally used as the point evaporation source is relatively large, which means the temperature at the upper portion of the crucible is higher than that at the lower portion thereof, and the temperature at the surrounding regions of the bottom of the crucible is higher than that at the center region of the bottom of the crucible. Therefore, when relatively large amount of material is filled in the crucible, material placed at the lower portion of the crucible, especially at the center region of the bottom of the crucible, will take longer time to be heated. In this case, the evaporation rate is relatively low. In order to raise the temperature inside the crucible and especially that at the center region of the bottom of the crucible, the overall temperature inside the crucible needs to be increased. For instance, in a case that the practical temperature required for the evaporation is 370° C., the temperature at the bottom of the crucible can merely reach 360° C. due to non-uniform heating and unsatisfactory heating conduction inside the crucible. Hence, the overall temperature inside the crucible needs to be increased to 380° C. or even 390° C., so that the temperature at the bottom, especially the center region of the bottom, of the crucible would attain 370° C. However, when the overall temperature inside the crucible is increased to 380° C. or above, the temperature at the upper portion of the crucible will reach the decomposition temperature of organic material, which means the organic material at the upper portion of the crucible may suffer a risk of decomposition. In particular, when material is provided with a relatively small amount, the temperature at the upper portion of the crucible often exceeds the decomposition temperature of the material under a high evaporation rate. Consequently, vaporized organic material is prone to decompose when passing through the upper portion of the crucible.

In order to solve the aforementioned problem, in prior art thermally conductive pellets 2′, usually small steel balls, are used for heat transfer, as shown in FIG. 5. That is to say, a layer of thermally conductive pellets 2′ are provided when a layer of organic material are added to the crucible. Therefore, heating temperature of the material in crucible 1′ can gradually become even due to the thermally conductive pellets 2′ added. Nevertheless, this solution is effective only when the material to be heated is that can be sublimated. As far as the material that can be melted type is concerned, it will be in the molten state at such a high temperature. As a result, these thermally conductive pellets 2′ would gradually accumulate at the bottom of the crucible 1′ because of different densities between the thermally conductive pellets 2′ and the organic material. Therefore, the pellets 2′ cannot play an effective role in heat transfer for the material in the upper portion as well as the middle portion of the crucible 1′. This will bring about a temperature difference within the crucible, particularly between the upper portion and the lower portion of the crucible 1′. Consequently, a uniform heating and heat transfer within the crucible 1′ cannot be achieved.

### SUMMARY OF THE INVENTION

The present disclosure aims to provide an evaporation device, through which a uniform heat transfer can be achieved and the overall heating temperature can be lowered, so that the decomposition of the organic material can be reduced.

The technical solution provided by the present solution relates to an evaporation device, including an evaporation device body, within which a plurality of thermal conductors that are contacted with one another for thermal conduction is disposed, wherein several holes are provided in each of the thermal conductors, and coating material for evaporation are provided within the holes of the thermal conductors, the spaces formed between the thermal conductors and the evaporation device body, and/or the spaces formed among the thermal conductors.

Compared with the prior art, the present disclosure has the following advantages. The thermal conductors, generally metal conductors having good conductivity, are disposed within the evaporation device body so that they can be contacted with one another, thus achieving a better heat transfer. Therefore, the temperature difference in the evaporation device body, especially between the upper portion and the lower portion thereof, is significantly reduced, or even no such a temperature difference exists. In this way, it is no longer necessary to heat the upper portion of the evaporation device body to an extent much higher than the preset temperature in order to attain the preset temperature at the bottom thereof. That is to say, it is sufficient to merely heat the upper portion of the evaporation device body to the preset temperature. For instance, to reach a preset temperature of 370° C., conventionally the upper portion has to be heated to a temperature of 380° C. or even higher; in contrast, according to the present disclosure, the upper portion can be heated only to the preset temperature of 370° C. In this case, the overall heating temperature can be lowered. As the result of that, the decomposition temperature of the organic material may not be reached or exceeded. Accordingly, decomposition of the organic material can be reduced.

As an improvement according to the present disclosure, the thermal conductor is a hollow, metal thermal conductor with several through-holes formed in the surface thereof, or a hollowed-out metal thermal conductor. The hollowed-out metal thermal conductor can be woven from metal wires or made through casting. The hollow or hollowed-out metal thermal conductor is relatively light-weight, so that more amount of organic material can be filled therein. Therefore, times of refilling can be reduced, and the efficiency of evaporation can be increased.

As a preferred option according to the present disclosure, the thermal conductor is a hollow polyhedron or a hollowed-out sphere. Both of the hollow polyhedron and the hollowed-out sphere can be easy to manufacture. In addition, they can be easily contacted with one another so as to generate heat transfer thereamong.

As another preferred option according to the present disclosure, there are polygonal holes and/or circular holes arranged in the surface of the hollow polyhedron or the hollowed-out sphere. Therefore, during filling, the coating material can be filled in the thermal conductors, or in the space formed among the thermal conductors, or in the space formed between the thermal conductors and the evaporation device body via the polygonal holes and/or circular holes. And during evaporation, the coating material being vaporized can outflow from the holes and the spaces.

As a further preferred option according to the present disclosure, the abovementioned thermal conductors include those made of aluminum, titanium, or aluminum alloy. Aluminum, titanium, or aluminum alloy are commonly used materials with great thermal conductivity and low cost.

As a further preferred option according to the present disclosure, the hollowed-out part of the thermal conductor amounts to 60%-98% of the total volume of the thermal conductor. Therefore, the thermal conductor can be filled with more organic material, and thus the evaporation rate can be increased.

In particular, as a further preferred option according to the present disclosure, the hollowed-out part of the thermal conductor amounts to 80%-90% of the total volume of the thermal conductor. The larger the hollowed-out part of the thermal conductor is, the more organic material can be filled therein. However, in this case, the efficiency of thermal conduction will be negatively influenced. In particular, when the hollowed-out part has occupied a certain proportion of the total volume, the effect of thermal conduction will get poorer as the volume of the hollowed-out part increases. If the hollowed-out part of the thermal conductor amounts to 80%-90% of the total volume of the thermal conductor, a good balance between the evaporation rate and the thermal conducting effect can be obtained.

As a further preferred option according to the present disclosure, the evaporation device body can be designed as a sealed crucible with a vaporization outlet. In this manner, heating and vaporizing can be promoted.

In addition, as a further preferred option according to the present disclosure, the preset temperature inside the crucible is 200° C.˜400° C. This is because the vaporization temperature of organic material used for thermal evaporation is generally lower than 400° C.

### BRIEF DESCRIPTION OF DRAWINGS

FIG. 1 schematically shows the structure of a evaporation device according to the present disclosure.

FIG. 2 shows a specific embodiment of the thermal conductor in FIG. 1.

FIG. 3 shows another specific embodiment of the thermal conductor in FIG. 1.

FIG. 4 shows a further specific embodiment of the thermal conductor in FIG. 1.

FIG. 5 schematically shows the structure of an evaporation device according to the prior art.

### LIST OF REFERENCE SIGNS

1 evaporation device body;

1.1 vaporization outlet;

2 thermal conductor;

3 hole;

3.1 polygonal hole;

3.2 circular hole;

4 space;

1′ crucible; and

2′ thermally conductive pellets.

### DETAILED DESCRIPTION OF EMBODIMENTS

The present disclosure will be further illustrated below with reference to the accompanying drawings and specific embodiments.

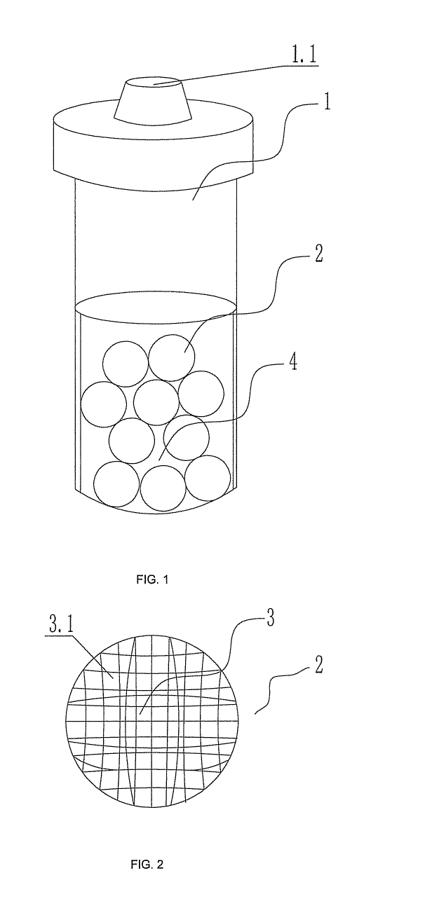

FIG. 1 shows a specific embodiment of the evaporation device according to the present disclosure. In this embodiment, the evaporation device includes an evaporation device body 1, in which a plurality of thermal conductors 2 that are contacted with one another for thermal conduction is disposed. Several holes 3 are formed in each of the thermal conductors 2. Coating material used for evaporation is provided in the holes 3 of the thermal conductors 2, the spaces 4 formed between the thermal conductors 2 and the evaporation device body 1, and/or the spaces 4 formed among the thermal conductors 2. In the present embodiment, the coating material is organic material.

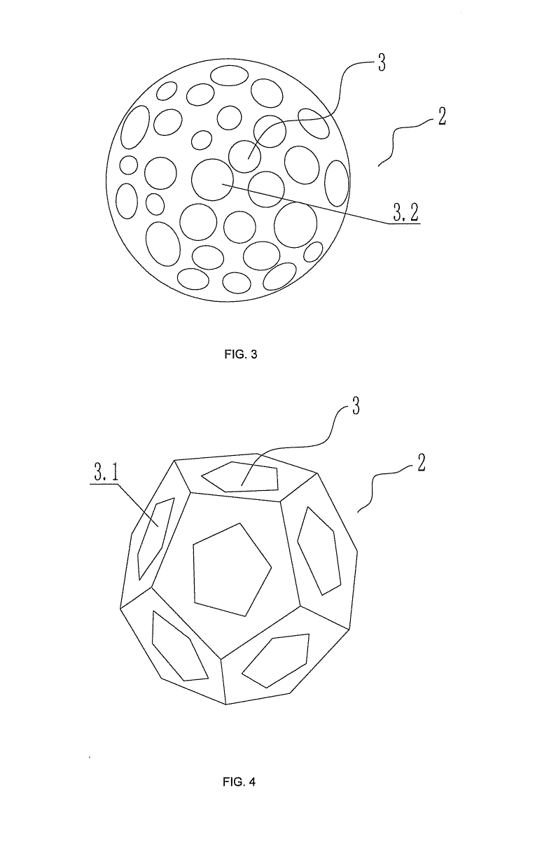

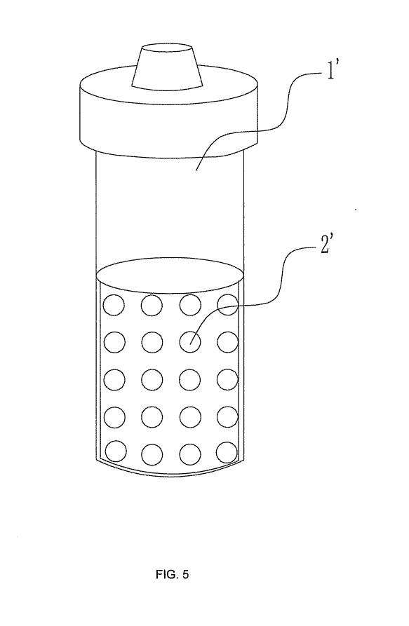

As shown in FIG. 2, FIG. 3, and FIG. 4, the thermal conductor 2 is a hollow, metal thermal conductor with several through-holes formed in the surface thereof, or a hollowed-out thermal conductor. Shape of the through-hole can be determined in accordance with the practical situation, though it can be preferably one or more of polygon, circle, or oval. Size of the through-hole can be determined based on the volumes of the evaporation device body 1 and the thermal conductor 2. The above-mentioned thermal conductor can be made of aluminum, titanium aluminum alloy, or titanium alloy. All of the three mentioned types of metal materials are ordinarily good in thermal conduction, light in weight, and low in cost.

As shown in FIG. 2, the thermal conductor 2 is a hollowed-out metal sphere that is woven from metal wires. The aforementioned metal wires are preferably titanium wires or titanium alloy wires. There are several polygonal holes 3.1 formed on the surface of the hollowed-out sphere.

As shown in FIG. 3, the thermal conductor 2 is a hollowed-out sphere with multiple circular holes 3.2 and/or oval holes in the surface thereof.

As shown in FIG. 4, the thermal conductor 2 is a hollowed-out polyhedron with multiple polygonal holes in the surface thereof. The polyhedron is preferably manufactured through casting aluminum or aluminum alloy.

For the purpose of improving productivity and evaporation efficiency, it is necessary to reduce the times of filling material. That is to say, coating material should be filled as much as possible at one single time. Therefore, volume of the hollowed-out part of the thermal conductor 2 should be increased to the greatest extent. In general, the hollowed-out part of the thermal conductor 2 can amount to 60%-98% of the total volume of the thermal conductor 2. Nevertheless, when the hollowed-out part has occupied a certain proportion of the total volume, the effect of thermal conduction will get poorer as the volume of the hollowed-out part increases. As a result, the hollowed-out part of the thermal conductor preferably amounts to 80%-90% of the total volume of the thermal conductor.

In the present embodiment, the evaporation device body 1 is in form of a sealed crucible with a vaporization outlet 1.1. In this case, the evaporation device body 1 can function as a crucible for heating. In the meantime, the evaporation device body 1 according to the present disclosure is designed as a sealed crucible with a vaporization outlet on the top thereof, as shown in FIG. 1, since the thermal evaporation is normally carried out under vacuum.

As a general rule, the preset temperature inside the crucible is 200° C.˜400° C. Different corresponding preset temperatures for evaporation should be selected for different coating materials. As far as a particular kind of coating material is concerned, an explicit preset temperature should be selected.

The evaporation method using the evaporation device disclosed in this present disclosure is similar to that using the evaporation device of the prior art.

Although the present disclosure has been described in conjunction with the preferred embodiments, it could be understood that various modifications or substitutes could be made to the present disclosure without departing from the scope of the present disclosure. Particularly, as long as structural conflicts do not exist, all features in all the embodiments may be combined together, and the formed combined features are still within the scope of the present disclosure. The present disclosure is not limited to the specific embodiments disclosed in the description, but includes all technical solutions falling into the scope of the claims.

1. An evaporation device, including an evaporation device body, within which a plurality of thermal conductors that are contacted with one another for thermal conduction is disposed, wherein several holes are provided in each of the thermal conductors, and coating material for evaporation are provided within the holes of the thermal conductors, the spaces formed between the thermal conductors and the evaporation device body, and/or the spaces formed among the thermal conductors.

2. The evaporation device according to claim 1, wherein the thermal conductor is a hollow, metal thermal conductor with several through-holes formed in the surface thereof, or a hollowed-out metal thermal conductor.

3. The evaporation device according to claim 2, wherein the thermal conductor is a hollow polyhedron or a hollowed-out sphere.

4. The evaporation device according to claim 3, wherein polygonal holes and/or circular holes are arranged in the surface of the hollow polyhedron or the hollowed-out sphere.

5. The evaporation device according to claim 4, wherein the thermal conductors include those made of aluminum, titanium, or aluminum alloy.

6. The evaporation device according to claim 1, wherein the hollowed-out part of the thermal conductor amounts to 60%-98% of the total volume of the thermal conductor.

7. The evaporation device according to claim 2, wherein the hollowed-out part of the thermal conductor amounts to 60%-98% of the total volume of the thermal conductor.

8. The evaporation device according to claim 3, wherein the hollowed-out part of the thermal conductor amounts to 60%-98% of the total volume of the thermal conductor.

9. The evaporation device according to claim 4, wherein the hollowed-out part of the thermal conductor amounts to 60%-98% of the total volume of the thermal conductor.

10. The evaporation device according to claim 5, wherein the hollowed-out part of the thermal conductor amounts to 60%-98% of the total volume of the thermal conductor.

11. The evaporation device according to claim 6, wherein the hollowed-out part of the thermal conductor amounts to 80%-90% of the total volume of the thermal conductor.

12. The evaporation device according to claim 7, wherein the hollowed-out part of the thermal conductor amounts to 80%-90% of the total volume of the thermal conductor.

13. The evaporation device according to claim 8, wherein the hollowed-out part of the thermal conductor amounts to 80%-90% of the total volume of the thermal conductor.

14. The evaporation device according to claim 9, wherein the hollowed-out part of the thermal conductor amounts to 80%-90% of the total volume of the thermal conductor.

15. The evaporation device according to claim 10, wherein the hollowed-out part of the thermal conductor amounts to 80%-90% of the total volume of the thermal conductor.

16. The evaporation device according to claim 1, wherein the evaporation device body is designed as a sealed crucible with a vaporization outlet.

17. The evaporation device according to claim 16, wherein the preset temperature inside the crucible is 200° C.˜400° C.
